(19) United States
(12) Patent Application Publication
(10) Pub. No.: US 2025/0037987 A1
(43) Pub. Date: Jan. 30, 2025

(54) METHODS OF FORMING ABRUPT INTERFACES BETWEEN SILICON-AND-CARBON-CONTAINING MATERIALS AND SILICON-AND-OXYGEN-CONTAINING MATERIALS

(71) Applicant: Applied Materials, Inc., Santa Clara, CA (US)

(72) Inventors: Stephen Weeks, Morrisville, VT (US); Hansel Lo, San Jose, CA (US); John Tolle, Gilbert, AZ (US); Christopher S. Olsen, Fremont, CA (US); Siddarth Krishnan, San Jose, CA (US)

(73) Assignee: Applied Materials, Inc., Santa Clara, CA (US)

(21) Appl. No.: 18/226,579

(22) Filed: Jul. 26, 2023

(51) Int. Cl. H01L 21/02

(52) U.S. Cl. CPC H01L 21/02164; H01L 21/02167; H01L 21/02236

(57) ABSTRACT

Exemplary semiconductor processing methods may include performing a pre-treatment on a substrate housed within a processing region of a semiconductor processing chamber. The substrate may include a layer of silicon-and-carbon-containing material. The pre-treatment may remove native oxide or residue from a surface of the layer of silicon-and-carbon-containing material. The methods may include providing a silicon-containing precursor to the processing region of the semiconductor processing chamber. The methods may include contacting the substrate with the silicon-containing precursor. The contacting may deposit a layer of silicon-containing material on the layer of silicon-and-carbon-containing material. The methods may include providing an oxygen-containing precursor to the processing region of the semiconductor processing chamber. The methods may include contacting the substrate with the oxygen-containing precursor. The contacting may oxidize the layer of silicon-containing material to form a layer of silicon-and-oxygen-containing material.

### TECHNICAL FIELD

The present technology relates to deposition processes and chambers. More specifically, the present technology relates to methods of producing abrupt interfaces between different materials.

### BACKGROUND

Integrated circuits are made possible by processes which produce intricately patterned material layers on substrate surfaces. Producing patterned material on a substrate requires controlled methods for forming and removing material. Material characteristics may affect how the device operates, and may also affect how the films are removed relative to one another. Plasma-enhanced deposition may produce films having certain characteristics. Many films that are formed require additional processing to adjust or enhance the material characteristics of the film in order to provide suitable properties.

Thus, there is a need for improved systems and methods that can be used to produce high quality devices and structures. These and other needs are addressed by the present technology.

### SUMMARY

Exemplary semiconductor processing methods may include performing a pre-treatment on a substrate housed within a processing region of a semiconductor processing chamber. The substrate may include a layer of silicon-and-carbon-containing material. The pre-treatment may remove native oxide or residue from a surface of the layer of silicon-and-carbon-containing material. The methods may include providing a silicon-containing precursor to the processing region of the semiconductor processing chamber. The methods may include contacting the substrate with the silicon-containing precursor. The contacting may deposit a layer of silicon-containing material on the layer of silicon-and-carbon-containing material. The methods may include providing an oxygen-containing precursor to the processing region of the semiconductor processing chamber. The methods may include contacting the substrate with the oxygen-containing precursor. The contacting may oxidize the layer of silicon-containing material to form a layer of silicon-and-oxygen-containing material.

In some embodiments, the methods may include forming plasma effluents of the silicon-containing precursor, the oxygen-containing precursor, or both. The plasma effluents of the silicon-containing precursor, the oxygen-containing precursor, or both may be formed at a plasma power of greater than or about 750 W. The pre-treatment may include annealing the substrate in an oxygen-free environment. The annealing may be performed at a temperature greater than or about 500° C. The pre-treatment may include: providing a halogen-containing precursor to the processing region, forming plasma effluents of the halogen-containing precursor, and contacting the substrate with the plasma effluents of the halogen-containing precursor. The contacting may remove the native oxide or residue from the surface of the layer of silicon-and-carbon-containing material. The halogen-containing precursor may be or include a fluorine-containing precursor. Depositing the layer of silicon-containing material may be or include a physical vapor deposition (PVD), a chemical vapor deposition (CVD), or an evaporation deposition. The layer of silicon-containing material may be characterized by a thickness of less than or about 400 Å. The oxygen-containing precursor may be or include diatomic oxygen (O₂), ozone (O₃), steam (H₂O), or hydrogen peroxide (H₂O₂). A temperature in the processing region may be maintained at less than or about 1,200° C. while contacting the substrate with the oxygen-containing precursor. A pressure in the processing region may be maintained at less than or about 20 Torr while contacting the substrate with the oxygen-containing precursor.

Some embodiments of the present technology may encompass semiconductor processing methods. The methods may include providing a silicon-containing precursor to a processing region of a semiconductor processing chamber. A substrate may be housed within the processing region. The substrate may include a layer of silicon-and-carbon-containing material. The methods may include contacting the substrate with the silicon-containing precursor, wherein the contacting deposits a layer of silicon-containing material on the layer of silicon-and-carbon-containing material. The layer of silicon-containing material may be characterized by a thickness of less than or about 400 Å. The methods may include providing an oxygen-containing precursor to the processing region of the semiconductor processing chamber. The methods may include contacting the substrate with the oxygen-containing precursor. The contacting may oxidize the layer of silicon-containing material to form a layer of silicon-and-oxygen-containing material.

In some embodiments, the layer of silicon-containing material may be or include amorphous silicon. The methods may include providing an aluminum-containing precursor or a hafnium-containing precursor to the processing region of the semiconductor processing chamber with the oxygen-containing precursor. The methods may include adjusting a temperature in the processing region while contacting the substrate with the oxygen-containing precursor. Contacting the substrate with the oxygen-containing precursor oxidizes only the layer of silicon-containing material. An interface between the layer of silicon-and-carbon-containing material and the layer of silicon-and-oxygen-containing material may be free of silicon-oxygen-and-carbon-containing material.

Some embodiments of the present technology may encompass semiconductor structures. The structures may include a substrate. The structures may include a layer of silicon-and-carbon-containing material overlying the substrate. The structures may include a layer of silicon-and-oxygen-containing material overlying the layer of silicon-and-carbon-containing material. An interface between the layer of silicon-and-carbon-containing material and the layer of silicon-and-oxygen-containing material may be free of silicon-oxygen-and-carbon-containing material.

In some embodiments, the layer of silicon-and-oxygen-containing material is formed by: depositing a layer of silicon-containing material and, subsequent an amount of deposition of the layer of silicon-containing material, oxidizing the layer of silicon-containing material to form the layer of silicon-and-oxygen-containing material.

Such technology may provide numerous benefits over conventional systems and techniques. For example, oxidizing a silicon-containing material instead of depositing a silicon-and-oxygen-containing material may reduce and/or prevent formation of silicon-oxygen-and-carbon-containing material at an interface with silicon-and-carbon-containing material. Additionally, preventing formation of silicon-oxygen-and-carbon-containing material at the interface between silicon-and-carbon-containing material and silicon-and-oxygen-containing material may lower the density of trap states that can limit mobility in transistor applications. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1 shows a top plan view of an exemplary processing system according to some embodiments of the present technology.

FIG. 2 shows a schematic cross-sectional view of an exemplary plasma system according to some embodiments of the present technology.

FIG. 3 shows operations of an exemplary method of semiconductor processing according to some embodiments of the present technology.

FIGS. 4A-4D show exemplary schematic cross-sectional structures in which material layers are included and produced according to some embodiments of the present technology.

Several of the figures are included as schematics. It is to be understood that the figures are for illustrative purposes, and are not to be considered of scale unless specifically stated to be of scale. Additionally, as schematics, the figures are provided to aid comprehension and may not include all aspects or information compared to realistic representations, and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

During semiconductor processing, structures may be produced that include one type of material directly overlying another type of material. For example, some transistor applications include a layer of silicon-and-oxygen-containing material overlying a layer of silicon-and-carbon-containing material. However, in many conventional operations to form a layer of silicon-and-oxygen-containing material, such as furnace oxidation, overlying a layer of silicon-and-carbon-containing material, silicon-oxygen-and-carbon material is formed at the interface between the materials. The presence of silicon-oxygen-and-carbon material may degrade final device performance. For example, silicon-oxygen-and-carbon material at the interface between silicon-and-oxygen-containing material and silicon-and-carbon-containing material may form trap states that may limit electron mobility in final devices and, therefore, degrade performance.

The present technology may overcome these issues by avoiding the formation of silicon-oxygen-and-carbon-containing material at the interface between two materials. By performing an initial silicon-containing material deposition followed by an oxidation of the silicon-containing material, formation of silicon-oxygen-and-carbon-containing material may be reduced and/or avoided. By preventing formation of silicon-oxygen-and-carbon-containing material at the interface, such as between silicon-and-carbon-containing material and silicon-and-oxygen-containing material, the density of trap states can be minimized, which may increase mobility in transistor applications.

Although the remaining disclosure will routinely identify specific deposition processes utilizing the disclosed technology, it will be readily understood that the systems and methods are equally applicable to other deposition chambers, as well as processes as may occur in the described chambers. Accordingly, the technology should not be considered to be so limited as for use with these specific deposition processes or chambers alone. The disclosure will discuss one possible system and chamber that may be used to perform deposition processes according to embodiments of the present technology before additional details according to embodiments of the present technology are described.

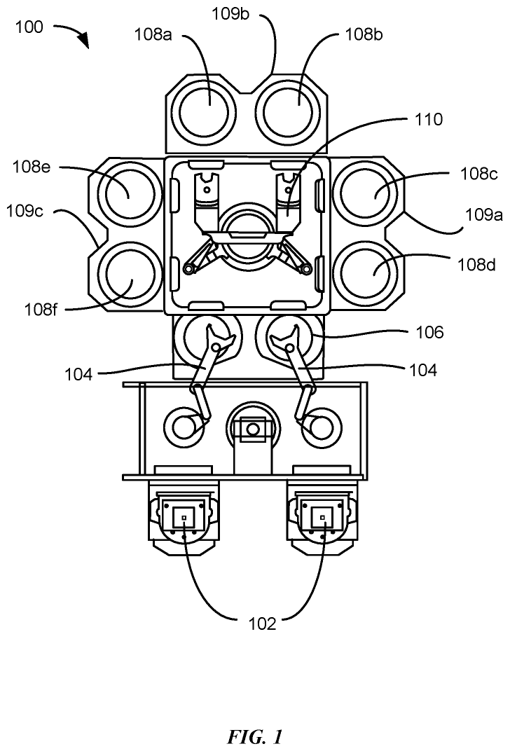

FIG. 1 shows a top plan view of one embodiment of a processing system 100 of deposition, etching, baking, and curing chambers according to embodiments. In the figure, a pair of front opening unified pods 102 supply substrates of a variety of sizes that are received by robotic arms 104 and placed into a low pressure holding area 106 before being placed into one of the substrate processing chambers 108a-f, positioned in tandem sections 109a-c. A second robotic arm 110 may be used to transport the substrate wafers from the holding area 106 to the substrate processing chambers 108a-f and back. Each substrate processing chamber 108a-f, can be outfitted to perform a number of substrate processing operations including formation of stacks of semiconductor materials described herein in addition to plasma-enhanced chemical vapor deposition, atomic layer deposition, physical vapor deposition, etch, pre-clean, degas, orientation, and other substrate processes including, annealing, ashing, etc.

The substrate processing chambers 108a-f may include one or more system components for depositing, annealing, curing and/or etching a dielectric or other film on the substrate or the substrate itself. In one configuration, two pairs of the processing chambers, e.g., 108c-d and 108e-f, may be used to deposit dielectric material on the substrate, and the third pair of processing chambers, e.g., 108a-b, may be used to etch the deposited dielectric. In another configuration, all three pairs of chambers, e.g., 108a-f, may be configured to deposit stacks of alternating dielectric films on the substrate. Any one or more of the processes described may be carried out in chambers separated from the fabrication system shown in different embodiments. It will be appreciated that additional configurations of deposition, etching, annealing, and curing chambers for dielectric films are contemplated by system 100.

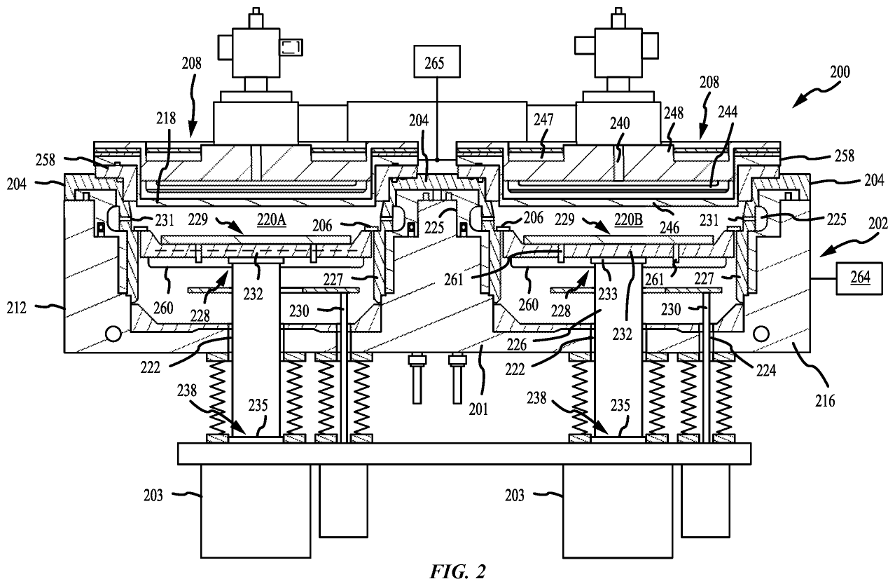

FIG. 2 shows a schematic cross-sectional view of an exemplary plasma system 200 according to some embodiments of the present technology. Plasma system 200 may illustrate a pair of processing chambers 108 that may be fitted in one or more of tandem sections 109 described above, and which may include lid stack components according to embodiments of the present technology, and as may be explained further below. The plasma system 200 generally may include a chamber body 202 having sidewalls 212, a bottom wall 216, and an interior sidewall 201 defining a pair of processing regions 220A and 220B. Each of the processing regions 220A-220B may be similarly configured, and may include identical components.

For example, processing region 220B, the components of which may also be included in processing region 220A, may include a pedestal 228 disposed in the processing region through a passage 222 formed in the bottom wall 216 in the plasma system 200. The pedestal 228 may provide a heater adapted to support a substrate 229 on an exposed surface of the pedestal, such as a body portion. The pedestal 228 may include heating elements 232, for example resistive heating elements, which may heat and control the substrate temperature at a desired process temperature. Pedestal 228 may also be heated by a remote heating element, such as a lamp assembly, or any other heating device.

The body of pedestal 228 may be coupled by a flange 233 to a stem 226. The stem 226 may electrically couple the pedestal 228 with a power outlet or power box 203. The power box 203 may include a drive system that controls the elevation and movement of the pedestal 228 within the processing region 220B. The stem 226 may also include electrical power interfaces to provide electrical power to the pedestal 228. The power box 203 may also include interfaces for electrical power and temperature indicators, such as a thermocouple interface. The stem 226 may include a base assembly 238 adapted to detachably couple with the power box 203. A circumferential ring 235 is shown above the power box 203. In some embodiments, the circumferential ring 235 may be a shoulder adapted as a mechanical stop or land configured to provide a mechanical interface between the base assembly 238 and the upper surface of the power box 203.

A rod 230 may be included through a passage 224 formed in the bottom wall 216 of the processing region 220B and may be utilized to position substrate lift pins 261 disposed through the body of pedestal 228. The substrate lift pins 261 may selectively space the substrate 229 from the pedestal to facilitate exchange of the substrate 229 with a robot utilized for transferring the substrate 229 into and out of the processing region 220B through a substrate transfer port 260.

A chamber lid 204 may be coupled with a top portion of the chamber body 202. The lid 204 may accommodate one or more precursor distribution systems 208 coupled thereto. The precursor distribution system 208 may include a precursor inlet passage 240 which may deliver reactant and cleaning precursors through a dual-channel showerhead 218 into the processing region 220B. The dual-channel showerhead 218 may include an annular base plate 248 having a blocker plate 244 disposed intermediate to a faceplate 246. A radio frequency (“RF”) source 265 may be coupled with the dual-channel showerhead 218, which may power the dual-channel showerhead 218 to facilitate generating a plasma region between the faceplate 246 of the dual-channel showerhead 218 and the pedestal 228. The dual-channel showerhead 218 and/or faceplate 246 may include one or more openings to permit the flow of precursors from the precursor distribution system 208 to the processing regions 220A and/or 220B. In some embodiments, the openings may include at least one of straight-shaped openings and conical-shaped openings. In some embodiments, the RF source may be coupled with other portions of the chamber body 202, such as the pedestal 228, to facilitate plasma generation. A dielectric isolator 258 may be disposed between the lid 204 and the dual-channel showerhead 218 to prevent conducting RF power to the lid 204. A shadow ring 206 may be disposed on the periphery of the pedestal 228 that engages the pedestal 228.

An optional cooling channel 247 may be formed in the annular base plate 248 of the precursor distribution system 208 to cool the annular base plate 248 during operation. A heat transfer fluid, such as water, ethylene glycol, a gas, or the like, may be circulated through the cooling channel 247 such that the base plate 248 may be maintained at a predefined temperature. A liner assembly 227 may be disposed within the processing region 220B in close proximity to the sidewalls 201, 212 of the chamber body 202 to prevent exposure of the sidewalls 201, 212 to the processing environment within the processing region 220B. The liner assembly 227 may include a circumferential pumping cavity 225, which may be coupled to a pumping system 264 configured to exhaust gases and byproducts from the processing region 220B and control the pressure within the processing region 220B. A plurality of exhaust ports 231 may be formed on the liner assembly 227. The exhaust ports 231 may be configured to allow the flow of gases from the processing region 220B to the circumferential pumping cavity 225 in a manner that promotes processing within the system 200.

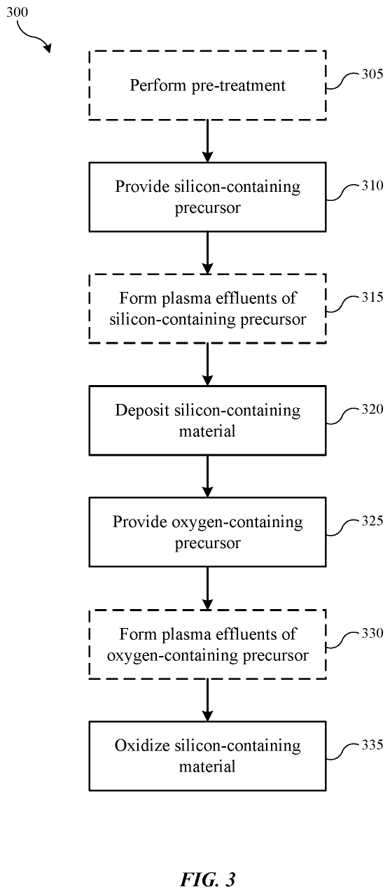

FIG. 3 shows exemplary operations in a processing method 300 according to some embodiments of the present technology. The method 300 may be performed in a variety of processing chambers, including plasma system 200 described above, as well as any other in which the operations may be performed. Method 300 may include a number of optional operations, which may or may not be specifically associated with some embodiments of methods according to the present technology. For example, many of the operations are described in order to provide a broader scope of the structural formation, but are not critical to the technology, or may be performed by alternative methodology as would be readily appreciated.

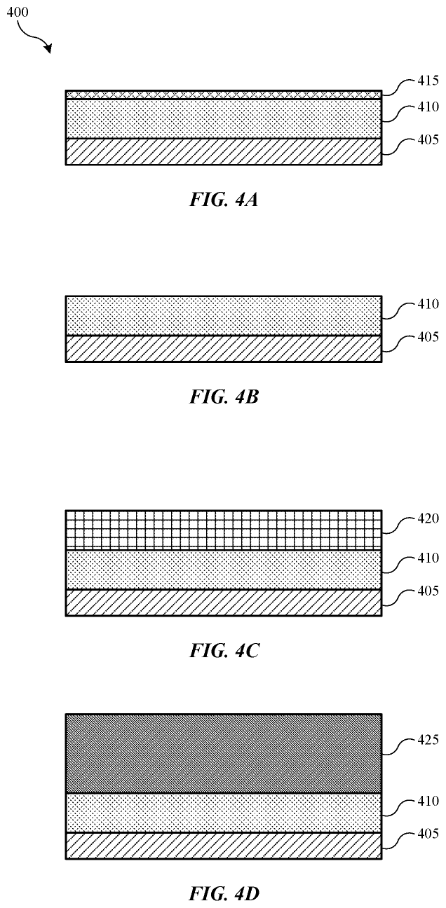

Method 300 may include additional operations prior to initiation of the listed operations. For example, additional processing operations may include forming structures on a semiconductor substrate, which may include both forming and removing material. Prior processing operations may be performed in the chamber in which method 300 may be performed, or processing may be performed in one or more other processing chambers prior to delivering the substrate into the semiconductor processing chamber in which method 300 may be performed. Regardless, method 300 may optionally include delivering a semiconductor substrate to a processing region of a semiconductor processing chamber, such as plasma system 200 described above, or other chambers that may include components as described above. The substrate may be deposited on a substrate support, which may be a pedestal, such as pedestal 228, and which may reside in a processing region of the chamber, such as region 220A or 220B described above. Method 300 describes operations shown schematically in FIGS. 4A-4D, the illustrations of which will be described in conjunction with the operations of method 300. It is to be understood that FIGS. 4A-4D illustrate only partial schematic views of an exemplary structure 400, and a substrate 405 may contain any number of additional materials and features having a variety of characteristics and aspects as illustrated in the figures.

As illustrated in FIG. 4A, in embodiments where prior processing is performed in one or more other processing chambers, a native oxide 415 may be present on a layer of silicon-and-carbon-containing material 410 disposed on the substrate 405. While the layer of silicon-and-carbon-containing material 410 is illustrated as being directly on the substrate 405, it is contemplated that any number of additional layers or materials may be disposed between substrate 405 and the layer of silicon-and-carbon-containing material 410. Additionally, while the layer of silicon-and-carbon-containing material 410 is shown as a blanket film in FIG. 4A, it is contemplated that the layer of silicon-and-carbon-containing material 410 may, in some embodiments, be characterized by any shape or dimension. For example, the layer of silicon-and-carbon-containing material 410 may be deposited over one or more features in one or more underlying materials.

At optional operation 305, method 300 may include performing a pre-treatment on the substrate 405 housed within the processing region of the semiconductor processing chamber. As illustrated in FIG. 4B, the pre-treatment at optional operation 305 may remove a native oxide 415 and/or residue from a surface of the layer of silicon-and-carbon-containing material 410. The present technology successfully forms an interface between silicon-and-carbon-containing material and silicon-and-oxygen-containing material that is free of silicon-oxygen-and-carbon-containing material. If native oxide were not removed, some silicon-oxygen-and-carbon-containing material may naturally be present at the interface between the silicon-and-carbon-containing material and the silicon-and-oxygen-containing material that is free of silicon-oxygen-and-carbon-containing material. Additionally, the removal of the native oxide 415 and/or residue may increase adhesion between the layer of silicon-and-carbon-containing material 410 and a subsequently formed layer of silicon-and-oxygen-containing material, such as the layer further discussed below.

Removing the native oxide 415 and/or residue from the surface of the layer of silicon-and-carbon-containing material 410 may include a high temperature anneal or a plasma-enhanced etch. In the high temperature anneal, the substrate 405 may be annealed in a non-oxidizing or a reducing environment to remove the native oxide 415 and/or residue. For example, the substrate 405 may be annealed in a hydrogen-containing environment or a nitrogen-containing environment, such as in diatomic hydrogen (H₂) or diatomic nitrogen (N₂). Annealing may be performed at a temperature greater than or about 500° C., and may be performed at a temperature greater than or about 550° C., greater than or about 600° C., greater than or about 650° C., greater than or about 700° C., greater than or about 750° C., greater than or about 800° C., greater than or about 850° C., greater than or about 900° C., greater than or about 1,000° C., greater than or about 1,100° C., greater than or about 1,200° C., greater than or about 1,300° C., greater than or about 1,400° C., or more. In some embodiments, the annealing may be performed at a temperature less than or about 1,500° C., and may be performed at less than or about 1,450° C., less than or about 1,400° C., or less.

Additionally or alternatively, the pre-treatment at optional operation 305 may include providing a halogen-containing precursor to the processing region, forming plasma effluents of the halogen-containing precursor, and contacting the substrate 405 with the plasma effluents of the halogen-containing precursor. The contacting may remove the native oxide 415 and/or residue from the surface of the layer of silicon-and-carbon-containing material 410. In embodiments, the halogen-containing precursor may be or include a fluorine-containing precursor, such as nitrogen trifluoride (NF₃). The halogen-containing precursor may also be provided with one or more hydrogen-containing precursors and/or nitrogen-containing precursors, such as H₂ and/or ammonia (NH₃).

During the pre-treatment at optional operation 305, implant-related damage may be reversed or healed. For example, the pre-treatment may remove residue from a previous implant operation. The residue may include, but is not limited to, carbon, fluorine, oxygen, or any other elements that may be used during implant operations. Specifically, these elements may be volatized and removed from the surface of the substrate 405. Additionally, high temperatures during the pre-treatment may rearrange the silicon-and-carbon-containing material 410, providing a material characterized by decreased roughness.

After removing the native oxide 415, if present, the method 300 may include providing a silicon-containing precursor to the processing region of the semiconductor processing chamber at operation 310. At optional operation 315, plasma effluents of the silicon-containing precursor may be formed. Method 300 may include contacting the substrate 405 with the silicon-containing precursor or plasma effluents thereof at operation 320. As illustrated in FIG. 4C, the contacting may deposit a layer of silicon-containing material 420 on the layer of silicon-and-carbon-containing material 410. The layer of silicon-containing material 420 may be deposited via any method including, but not limited to, physical vapor deposition (PVD), chemical vapor deposition (CVD), or evaporation deposition.

Silicon-containing precursors that may be used may include, but are not limited to, silane (SiH₄), disilane (Si₂H₆), silicon tetrafluoride (SiF₄), silicon tetrachloride (SiCl₄), dichlorosilane (SiH₂Cl₂), tetraethyl orthosilicate (TEOS), as well as any other silicon-containing precursors that may be used or useful in silicon-containing material formation. In embodiments, one or more additional precursors may be provided to adjust mechanical properties of the layer of silicon-containing material 420. For example, to increase the dielectric constant of the layer of silicon-containing material 420, an aluminum-containing precursor and/or a hafnium-containing precursor may be combined or provided with the silicon-containing precursor. The aluminum-containing precursor and the hafnium-containing precursor may be any material that is used or useful in forming high dielectric constant silicon-containing material. A carrier gas may be combined or provided with the silicon-containing precursor provided to the processing region of the semiconductor processing chamber. In embodiments, the carrier gas may be one or more of helium, argon, and molecular nitrogen (N₂), among other carrier gases.

As previously discussed, some embodiments may include forming plasma effluents of the silicon-containing precursor at optional operation 315. In embodiments, the plasma effluents of the silicon-containing precursor may be formed at a plasma power of greater than or about 750 W, and may be formed at greater than or about 1,000 W, greater than or about 1,250 W, greater than or about 1,500 W, greater than or about 1,750 W, greater than or about 2,000 W, greater than or about 2,250 W, greater than or about 2,500 W, greater than or about 2,750 W, greater than or about 3,000 W, greater than or about 3,500 W, greater than or about 4,000 W, greater than or about 4,500 W, greater than or about 5,000 W, greater than or about 5,500 W, greater than or about 6,000 W, or more. Plasma power may be selected to adjust the deposition rate and resultant microstructure of the deposited material. For example, a higher plasma power may induce higher ionization/dissociation of the silicon-containing precursor which may increase deposition rate. However, increased plasma powers may result in densification of the deposited material and/or sputtering of the deposited film.

The layer of silicon-containing material 420 deposited on the layer of silicon-and-carbon-containing material 410 may be an amorphous silicon-containing material, such as amorphous silicon. Depending on the application, the layer of silicon-containing material 420 may be characterized by a thickness of less than or about 400 Å. At greater thicknesses, a subsequent operation to oxidize the layer of silicon-containing material 420 may require extensive contacting to oxidize an entire thickness of the layer of silicon-containing material 420. Accordingly, the layer of silicon-containing material 420 may be characterized by a thickness of less than or about 375 Å, less than or about 350 Å, less than or about 325 Å, less than or about 300 Å, less than or about 275 Å, less than or about 250 Å, less than or about 225 Å, less than or about 200 Å, less than or about 175 Å, less than or about 150 Å, less than or about 125 Å, less than or about 100 Å, less than or about 75 Å, less than or about 50 Å, less than or about 25 Å, or less. However, at reduced thicknesses the subsequent operation to oxidize the layer of silicon-containing material 420 may become increasingly difficult to avoid oxidizing the underlying layer of silicon-and-carbon-containing material 410 and avoiding the formation of silicon-oxygen-and-carbon-containing material at the interface between layer of silicon-and-carbon-containing material 410 and the layer of silicon-containing material 420.

Subsequent an amount of deposition of the layer of silicon-containing material 420, method 300 may include providing an oxygen-containing precursor to the processing region of the semiconductor processing chamber at operation 325. At optional operation 330, plasma effluents of the oxygen-containing precursor may be formed. Method 300 may include contacting the substrate 405 with the oxygen-containing precursor or plasma effluents thereof at operation 335. As illustrated in FIG. 4D, the contacting may oxidize the layer of silicon-containing material 420 to form a layer of silicon-and-oxygen-containing material 425.

In embodiments, a flow of the silicon-containing precursor may be halted prior to providing the oxygen-containing precursor to the processing region of the semiconductor processing chamber. However, it is also contemplated that the flow of the silicon-containing precursor may be maintained while providing the oxygen-containing precursor to the processing region of the semiconductor processing chamber. In embodiments, the flow of the silicon-containing precursor may also be increased or decreased while providing the oxygen-containing precursor to the processing region of the semiconductor processing chamber.

Oxygen-containing precursors that may be used may include, but are not limited to, diatomic oxygen (O₂), nitrous oxide (N₂O), nitrogen dioxide (NO₂), ozone (O₃), steam (H₂O), hydrogen peroxide (H₂O₂), as well as any other oxygen-containing precursors that may be used in silicon-containing material formation, such as silicon-and-oxygen-containing material formation. The oxygen-containing precursor may be provided with a hydrogen-containing precursor, such as diatomic hydrogen (H₂). A carrier gas may be combined or provided with the oxygen-containing precursor provided to the processing region of the semiconductor processing chamber. In embodiments, the carrier gas may be one or more of helium, argon, and molecular nitrogen (N₂), among other carrier gases.

Similar to the silicon-containing precursor, some embodiments may include forming plasma effluents of the oxygen-containing precursor at optional operation 330. In embodiments, the plasma effluents of the oxygen-containing precursor may be formed at a plasma power of greater than or about 750 W, and may be formed at greater than or about 1,000 W, greater than or about 1,250 W, greater than or about 1,500 W, greater than or about 1,750 W, greater than or about 2,000 W, greater than or about 2,250 W, greater than or about 2,500 W, greater than or about 2,750 W, greater than or about 3,000 W, greater than or about 3,500 W, greater than or about 4,000 W, greater than or about 4,500 W, greater than or about 5,000 W, greater than or about 5,500 W, greater than or about 6,000 W, or more. Higher plasma powers, such as plasma powers greater than 750 W, may increase oxidation rate.

While contacting the substrate 405 with the oxygen-containing precursor or plasma effluents thereof at operation 335, the layer of silicon-containing material 420 may be oxidized. In some embodiments, the contacting may oxidize only the layer of silicon-containing material 420 and may not oxidize the layer of silicon-and-carbon-containing material 410 and/or the substrate 405. Accordingly, an interface between the layer of silicon-and-carbon-containing material 410 and the layer of silicon-and-oxygen-containing material 420 may be free of silicon-oxygen-and-carbon-containing material when the layer of silicon-and-oxygen-containing material 420 is oxidized to form the layer of silicon-and-oxygen-containing material 425. In embodiments, Si—O bonds my form in the layer of silicon-containing material 420 to produce the layer of silicon-and-oxygen-containing material 425. During the oxidation, a thickness of the layer of silicon-containing material 420 may increase due to the incorporation of oxygen. For example, during the conversion of the layer of silicon-containing material 420 to the layer of silicon-and-oxygen-containing material 425, a thickness of the material may increase by greater than or about 60%, greater than or about 65%, greater than or about 70%, greater than or about 75%, greater than or about 80%, greater than or about 85%, greater than or about 90%, greater than or about 95%, greater than or about 100%, greater than or about 105%, or more.

Because of the reaction being performed in some embodiments, the semiconductor processing chamber, the pedestal, or the substrate 405 may be maintained at a temperature greater than or about 750° C., and in some embodiments may be maintained at a temperature that is greater than or about 800° C., greater than or about 850° C., greater than or about 900° C., greater than or about 925° C., greater than or about 950° C., greater than or about 975° C., greater than or about 1,000° C., greater than or about 1,025° C., greater than or about 1,050° C., greater than or about 1,075° C., greater than or about 1,100° C., greater than or about 1,125° C., greater than or about 1,150° C., greater than or about 1,175° C., greater than or about 1,200° C., greater than or about 1,225° C., greater than or about 1,250° C., or more. By increasing the temperature, oxidation of the layer of silicon-containing material 420 may be increased and the quality of the silicon-and-oxygen-containing material 425 may be increased. Conversely, by decreasing the temperature, the selectivity of the oxidation of the layer of silicon-containing material 420 relative to the layer of silicon-and-carbon-containing material 410 may be increased. Accordingly, in some embodiments, the semiconductor processing chamber, the pedestal, or the substrate 405 may be maintained at a temperature less than or about 1,200° C., and in some embodiments may be maintained at a temperature that is less than or about 1,150° C., less than or about 1,100° C., less than or about 1,050° C., less than or about 1,000° C., less than or about 950° C., less than or about 900° C., less than or about 850° C., less than or about 800° C., less than or about 750° C., or less. In some embodiments, temperature may be adjusted, such as during operation 335, to control the oxidation of the layer of silicon-containing material 420. For example, the temperature may be reduced after a first period of time to achieve better selectivity of the oxidation when the oxidation is approaching the interface between the layer of silicon-containing material 420 and the layer of silicon-and-carbon-containing material 410.

The semiconductor processing chamber may be maintained at a pressure less than or about 20 Torr, and in some embodiments may be maintained at a pressure that is less than or about 18 Torr, less than or about 16 Torr, less than or about 14 Torr, less than or about 12 Torr, less than or about 10 Torr, less than or about 8 Torr, less than or about 6 Torr, less than or about 4 Torr, less than or about 2 Torr, less than or about 1 Torr, or less. However, in some embodiments, the processing chamber may be maintained at atmospheric conditions.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a precursor” includes a plurality of such precursors, and reference to “the layer of material” includes reference to one or more layers of materials and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

1. A semiconductor processing method comprising:
performing a pre-treatment on a substrate housed within a processing region of a semiconductor processing chamber, wherein the substrate comprises a layer of silicon-and-carbon-containing material, and wherein the pre-treatment removes native oxide or residue from a surface of the layer of silicon-and-carbon-containing material;
providing a silicon-containing precursor to the processing region of the semiconductor processing chamber;
contacting the substrate with the silicon-containing precursor, wherein the contacting deposits a layer of silicon-containing material on the layer of silicon-and-carbon-containing material;
providing an oxygen-containing precursor to the processing region of the semiconductor processing chamber; and
contacting the substrate with the oxygen-containing precursor, wherein the contacting oxidizes the layer of silicon-containing material to form a layer of silicon-and-oxygen-containing material.

2. The semiconductor processing method of claim 1, further comprising:
forming plasma effluents of the silicon-containing precursor, the oxygen-containing precursor, or both.

3. The semiconductor processing method of claim 2, wherein the plasma effluents of the silicon-containing precursor, the oxygen-containing precursor, or both are formed at a plasma power of greater than or about 750 W.

4. The semiconductor processing method of claim 1, wherein the pre-treatment comprises annealing the substrate in an oxygen-free environment.

5. The semiconductor processing method of claim 4, wherein the annealing is performed at a temperature greater than or about 500° C.

6. The semiconductor processing method of claim 1, wherein the pre-treatment comprises:
providing a halogen-containing precursor to the processing region;
forming plasma effluents of the halogen-containing precursor; and
contacting the substrate with the plasma effluents of the halogen-containing precursor, wherein the contacting removes the native oxide or residue from the surface of the layer of silicon-and-carbon-containing material.

7. The semiconductor processing method of claim 6, wherein the halogen-containing precursor comprises a fluorine-containing precursor.

8. The semiconductor processing method of claim 1, wherein depositing the layer of silicon-containing material comprises a physical vapor deposition (PVD), a chemical vapor deposition (CVD), or an evaporation deposition.

9. The semiconductor processing method of claim 1, wherein the layer of silicon-containing material is characterized by a thickness of less than or about 400 Å.

10. The semiconductor processing method of claim 1, wherein the oxygen-containing precursor comprises diatomic oxygen (O₂), ozone (O₃), steam (H₂O), or hydrogen peroxide (H₂O₂).

11. The semiconductor processing method of claim 1, wherein a temperature in the processing region is maintained at less than or about 1,200° C. while contacting the substrate with the oxygen-containing precursor.

12. The semiconductor processing method of claim 11, wherein a pressure in the processing region is maintained at less than or about 20 Torr while contacting the substrate with the oxygen-containing precursor.

13. A semiconductor processing method comprising:
providing a silicon-containing precursor to a processing region of a semiconductor processing chamber, wherein a substrate is housed within the processing region, and wherein the substrate comprises a layer of silicon-and-carbon-containing material;
contacting the substrate with the silicon-containing precursor, wherein the contacting deposits a layer of silicon-containing material on the layer of silicon-and-carbon-containing material, and wherein the layer of silicon-containing material is characterized by a thickness of less than or about 400 Å;
providing an oxygen-containing precursor to the processing region of the semiconductor processing chamber; and
contacting the substrate with the oxygen-containing precursor, wherein the contacting oxidizes the layer of silicon-containing material to form a layer of silicon-and-oxygen-containing material.

14. The semiconductor processing method of claim 13, wherein the layer of silicon-containing material comprises amorphous silicon.

15. The semiconductor processing method of claim 13, further comprising:
providing an aluminum-containing precursor or a hafnium-containing precursor to the processing region of the semiconductor processing chamber with the oxygen-containing precursor.

16. The semiconductor processing method of claim 13, further comprising:
adjusting a temperature in the processing region while contacting the substrate with the oxygen-containing precursor.

17. The semiconductor processing method of claim 13, wherein contacting the substrate with the oxygen-containing precursor oxidizes only the layer of silicon-containing material.

18. The semiconductor processing method of claim 13, wherein an interface between the layer of silicon-and-carbon-containing material and the layer of silicon-and-oxygen-containing material is free of silicon-oxygen-and-carbon-containing material.

19. A semiconductor structure comprising:
a substrate;
a layer of silicon-and-carbon-containing material overlying the substrate; and
a layer of silicon-and-oxygen-containing material overlying the layer of silicon-and-carbon-containing material, wherein an interface between the layer of silicon-and-carbon-containing material and the layer of silicon-and-oxygen-containing material is free of silicon-oxygen-and-carbon-containing material.

20. The semiconductor structure of claim 19, wherein the layer of silicon-and-oxygen-containing material is formed by:
depositing a layer of silicon-containing material; and
subsequent an amount of deposition of the layer of silicon-containing material, oxidizing the layer of silicon-containing material to form the layer of silicon-and-oxygen-containing material.
